(19) United States
(12) Patent Application Publication
(10) Pub. No.: US 2008/0048221 A1
(43) Pub. Date: Feb. 28, 2008

(54) Image sensor and manufacturing method thereof

(76) Inventor: Chang-Eun Lee, Seoul (KR)

Correspondence Address: SHERR & NOURSE, PLLC, 620 HERNDON PARKWAY, SUITE 200, HERNDON, VA, 20170, US

(21) Appl. No.: 11/841,029

(22) Filed: Aug. 20, 2007

(30) Foreign Application Priority Data
Aug. 22, 2006 (KR) 10-2006-0079320

(51) Int. Cl. H01L 27/146; H01L 31/062; H01L 31/18

(52) U.S. Cl. 257/292; 438/59; 257/E27.133; 257/E31.085

(57) ABSTRACT

Embodiments relate to an image sensor and a method for manufacturing an image sensor. According to embodiments, ions of low concentration may be implanted into a photodiode region of a semiconductor substrate to form a photodiode. At least one gate insulating layer pattern may be formed on the semiconductor substrate, and a gate electrode may be formed on each of the at least one gate insulating layer pattern to receive charges from the photodiode. Spacers may be formed at sidewalls of the gate electrode, respectively. A selective epitaxial growth layer may be formed on the photodiode, and ions of low concentration may be obliquely implanted into one side and the other side of the gate electrode to form a low concentration source and a low concentration drain extending below the spacer. Subsequently, a high concentration source and a high concentration drain may be formed on both sides of the gate electrode, respectively.

The present application claims priority under 35 U.S.C. 119 and 35 U.S.C. 365 to Korean Patent Application No. 10-2006-0079320 (filed on Aug. 22, 2006), which is hereby incorporated by reference in its entirety.

### BACKGROUND

An image sensor may be a semiconductor device configured to convert optical images into electrical signals. Image sensors may be divided into charged coupled devices (CCDs) and complementary metal oxide semiconductor (CMOS) image sensors.

A CMOS image sensor may include a photodiode and a MOS transistor in a unit pixel, and may sequentially detect electrical signals in a switching manner to realize an image.

CMOS image sensors may be divided into 3T type CMOS image sensors having three transistors, 4T type CMOS image sensors having four transistors, and 5T type CMOS image sensors having five transistors, according to a number of transistors.

Since a photodiode of an image sensor that generates charges according to an amount of light may be exposed to an outside, the photodiode may physically and chemically combine with particles from the outside, which may reduce a characteristic of the photodiode.

### SUMMARY

Embodiments relate to an image sensor and a manufacturing method thereof. Embodiments may provide an image sensor and a manufacturing method thereof that may prevent contamination of a photodiode.

According to embodiments, an image sensor may include a photodiode for generating charges according to light incident thereto, a selective epitaxial growth layer disposed on the photodiode, and a plurality of thin film transistors for outputting a voltage corresponding to charges output from the photodiode.

According to embodiments, a method for manufacturing an image sensor may include implanting ions of low concentration into a photodiode region of a semiconductor substrate to form a photodiode, forming at least one gate insulating layer pattern on the semiconductor substrate, and a gate electrode on each at least one gate insulating layer pattern to receive charges from the photodiode, forming a spacer at sidewalls of the gate electrode, forming a selective epitaxial growth layer on the photodiode, obliquely implanting ions of low concentration into one side and the other side of the gate electrode to form a low concentration source and a low concentration drain extending below the spacer, and forming a high concentration source and a high concentration drain on both sides of the gate electrode, respectively.

### DRAWINGS

FIG. 1 is a circuit diagram of an image sensor according to embodiments.

FIG. 2 is a plan layout of the image sensor of FIG. 1.

FIG. 3 is a cross-sectional view of a photodiode, a transfer transistor, and a reset transistor according to embodiments.

FIG. 4 is a cross-sectional view of a photodiode, a transfer transistor, and a reset transistor according to embodiments.

FIGS. 5 to 10 are cross-sectional views illustrating a process of manufacturing the image sensor according to embodiments.

### DETAILED DESCRIPTION

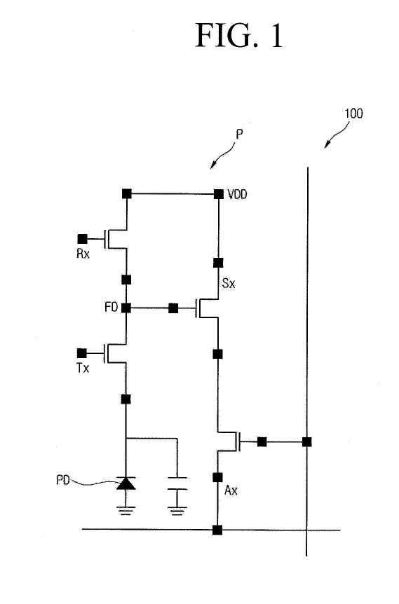

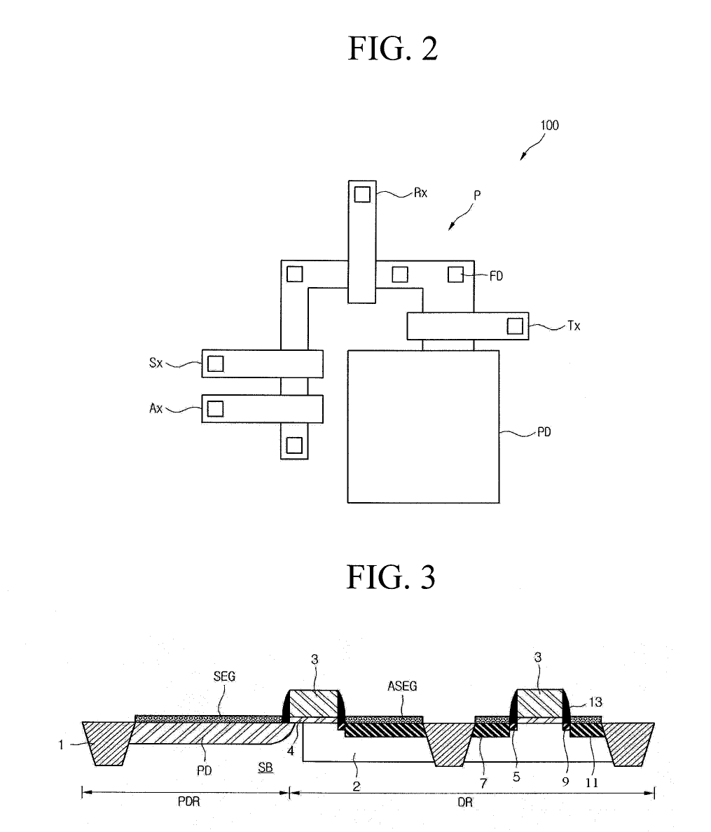

FIG. 1 is a circuit diagram of an image sensor according to embodiments, and FIG. 2 is a plan layout of the image sensor of FIG. 1.

Referring to FIGS. 1 and 2, one of a plurality of pixels of an image sensor may include photodiode PD to detect external light, and a plurality of transistors to control transmission and/or output of charges stored in photodiode PD. In embodiments, the pixel of image sensor 100 may be described with respect to a four transistor device, but any number could be used.

Pixel P may include photodiode PD to detect light, transfer transistor Tx, reset transistor Rx, select transistor Sx, and access transistor Ax.

Transfer transistor Tx and reset transistor Rx may be connected in series to photodiode PD. The source of transfer transistor Tx may be connected to photodiode PD, and the drain of transfer transistor Tx may be connected to the source of reset transistor Rx. A power voltage Vdd may be applied to the drain of reset transistor Rx.

The drain of transfer transistor Tx may serve as a floating diffusion (FD) layer. The FD layer may be connected to the gate of select transistor Sx. Select transistor Sx and access transistor Ax may be connected with each other in series. In embodiments, the source of select transistor Sx and the drain of access transistor Ax may be connected with each other. A power voltage Vdd may be applied to the drain of access transistor Ax and the source of reset transistor Rx. The drain of select transistor Sx may correspond to an output terminal, and a selection signal Row may be applied to the gate of select transistor Sx.

An operation of pixel P of image sensor 100 according to embodiments, for example having the above structure, will be briefly described. First, reset transistor Rx may be turned on to make potential of the FD layer equal to the power voltage Vdd. Next, reset transistor Rx may be turned off. Such an operation may be defined as a reset operation.

When external light is incident to photodiode PD, electron-hole pairs (EHPs) may be created inside photodiode PD. Signal charges may thus be accumulated inside photodiode PD. Subsequently, if transfer transistor Tx is turned on, the signal charges accumulated inside photodiode PD may be output to and stored in the FD layer. Accordingly, the potential of the FD layer may change in proportion to charges output from photodiode PD, so that the potential of the gate of access transistor Ax changes. At this point, select transistor Sx may be turned on by a selection signal Row, data may be output to an output terminal. After data is output, pixel P may perform a reset operation again. Pixel P may repeat these processes and may convert light into electrical signals and output the converted signals.

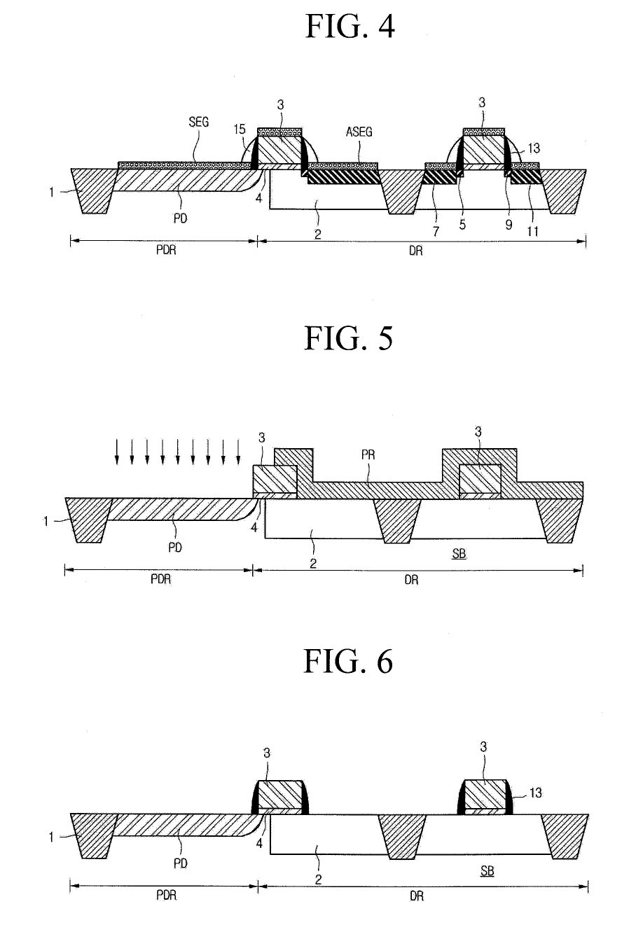

FIG. 3 is a cross-sectional view of a photodiode, a transfer transistor, and a reset transistor according to embodiments.

Referring to FIG. 3, a plurality of device isolation portions 1 may be disposed in semiconductor substrate SB. In embodiments, device isolation portion 1 may be formed by forming a trench in semiconductor substrate SB and filling the trench with oxides.

Photodiode PD may be disposed in photodiode region PDR formed in semiconductor substrate SB. Photodiode PD may include low concentration doped n-type ions.

In embodiments, selective epitaxial growth layer SEG may be formed on photodiode PD disposed in photodiode region PDR. Selective epitaxial growth layer SEG may completely cover photodiode PD and may prevent photodiode PD from being contaminated by external particles and conductive impurities.

In embodiments, driving region DR may be disposed in a region of semiconductor substrate SB that may be adjacent to photodiode region PDR. A plurality of transistors may be disposed in driving region DR.

In embodiments, the plurality of transistors may be transfer transistor Tx, reset transistor Rx, select transistor Sx, and access transistor Ax as illustrated in FIGS. 1 and 2.

FIG. 3 illustrates transfer transistor Tx and reset transistor Rx according to embodiments.

Each of the above-mentioned thin film transistors Tx, Rx, Sx, and Ax may include gate 3, gate insulating layer 4, low concentration source 5, high concentration source 7, low concentration drain 9, and high concentration drain 11.

Gate 3 may be disposed on gate insulating layer 4. Low concentration source 5 doped with n-type impurities, and low concentration drain 9 doped with n-type impurities may be formed in both sides of gate 3, respectively.

Gate spacers 13 may be disposed at sidewalls of gate 3. n-type high concentration impurities may be selectively implanted into driving region DR of semiconductor substrate SB using gate spacers 13 as an ion implantation mask, and may form high concentration source 7 and high concentration drain 11. Thin film transistors Tx, Rx, Sx, and Ax may thus be manufactured as illustrated in FIGS. 1 and 2.

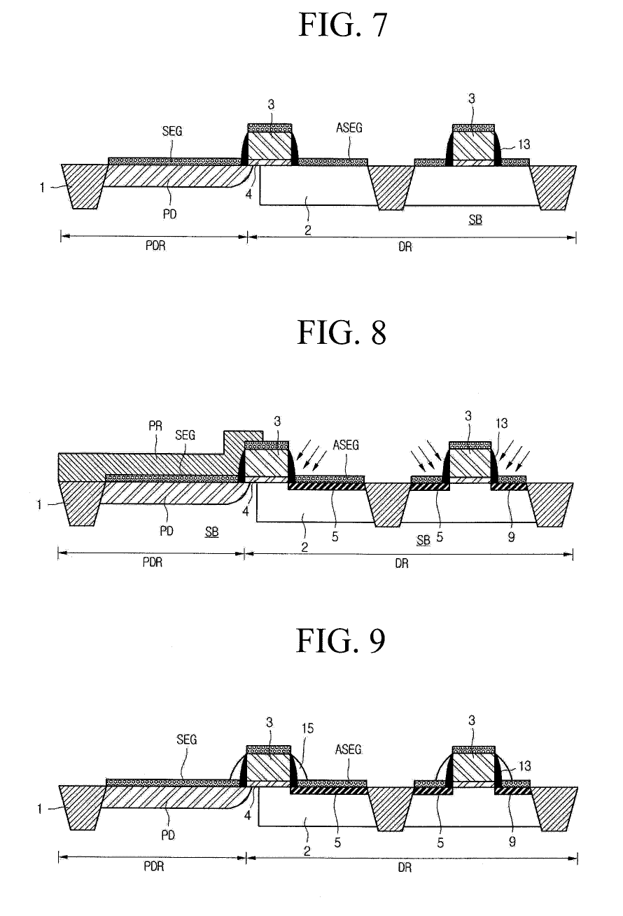

FIG. 4 is a cross-sectional view of photodiode, transfer transistor, and reset transistor according to embodiments.

Referring to FIG. 4, a plurality of device isolation portions 1 may be disposed in semiconductor substrate SB. In embodiments, device isolation portion 1 may be formed by forming a trench in semiconductor substrate SB and filling the trench with oxides.

Photodiode PD may be disposed in photodiode region PDR that may be formed in semiconductor substrate SB. Photodiode PD may include doped n-type ions of low concentration.

In embodiments, selective epitaxial growth layer SEG may be formed on photodiode PD disposed in photodiode region PDR. Selective epitaxial growth layer SEG may completely cover photodiode PD, which may prevent photodiode PD from being contaminated by external particles and conductive impurities.

In embodiments, driving region DR may be disposed in a region of semiconductor substrate SB that may be adjacent to photodiode region PDR. A plurality of transistors may be disposed in driving region DR.

In embodiments, the plurality of transistors may be transfer transistor Tx, reset transistor Rx, select transistor Sx, and access transistor Ax as illustrated in FIGS. 1 and 2. In embodiments, FIG. 3 illustrates transfer transistor Tx and reset transistor Rx.

Each of the above-mentioned thin film transistors Tx, Rx, Sx, and Ax may include gate 3, gate insulating layer 4, low concentration source 5, high concentration source 7, low concentration drain 9, and high concentration drain 11.

Gate 3 may be disposed on gate insulating layer 4, and gate spacers 13 may be disposed at both sidewalls of gate 3, respectively.

In embodiments, additional selective epitaxial growth layer ASEG may be additionally provided on a portion of semiconductor substrate SB not covered with the upper surface of gate 3 and gate spacers 13. In embodiments, additional selective epitaxial growth layer ASEG may be formed to correspond to low concentration source 5, high concentration source 7, low concentration drain 9, and high concentration drain 11, for example.

In embodiments, low concentration source 5 doped with n-type low concentration ions, and low concentration drain 9 doped with n-type low concentration impurities may be disposed in portions of semiconductor substrate SB below gate spacers 13 by obliquely implanting the n-type impurities. In embodiments, low concentration source 5 and low concentration drain 9 extend below gate spacers 13.

Additional gate spacers 15 may be disposed on the surfaces of gate spacers 13. Additional gate spacers 15 may be disposed on a surface of gate spacers 13 and on additional selective epitaxial growth layer ASEG.

High concentration source 7 and high concentration drain 11 may include n-type impurities. The high concentration n-type impurities may be implanted into semiconductor substrate SB using additional gate spacers 15 as an ion implantation mask.

In embodiments, not only selective epitaxial growth layer SEG may be formed on photodiode PD, but also additional selective epitaxial growth layer ASEG may be formed on low concentration source 5, high concentration source 7, low concentration drain 9, and high concentration drain 11, so that additional selective epitaxial growth layer ASEG reduces the implantation depth of the n-type impurities implanted into low concentration source 5, high concentration source 7, low concentration drain 9, and high concentration drain 11.

In embodiments, the shallow junction characteristics of low concentration source 5, high concentration source 7, low concentration drain 9, and high concentration drain 11 may be easily realized.

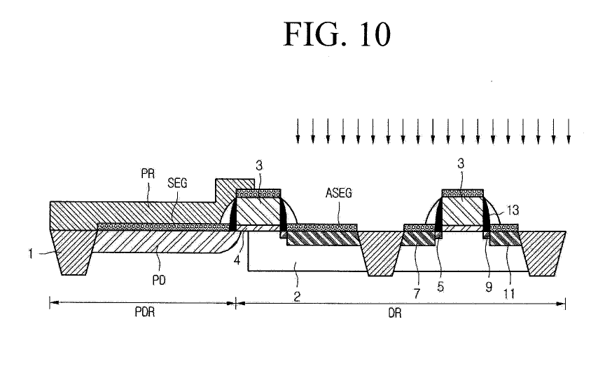

FIGS. 5 to 10 are cross-sectional views illustrating a process of manufacturing an image sensor according to embodiments.

Referring to FIG. 5, device isolation portion 1 may be formed in semiconductor substrate SB. IN embodiments, device isolation portion 1 may be formed by forming a trench in semiconductor substrate SB and filling the trench with oxides.

After device isolation portion 1 is formed, a driving region DR of semiconductor substrate SB, in which transistors may be formed, may be doped with low concentration p-type ions, so that a P well 2 may be formed.

A gate insulating layer and a gate silicon layer may be sequentially formed over a surface, for example an entire surface, of semiconductor substrate SB. The gate insulating layer and the gate silicon layer may then be patterned to form gate insulating layer pattern 4 and gate 3 on gate insulating layer pattern 4.

In embodiments, low concentration n-type impurities may be selectively implanted into a photodiode region PDR with driving region DR covered with photoresist pattern PR to form photo diode PD doped with the low concentration n-type impurities in photodiode region PDR.

Referring to FIG. 6, after photodiode PD is formed, photoresist PR that has covered driving region DR may be removed. An insulating layer (not shown) covering photodiode PD and gate 3 may be formed on semiconductor substrate SB. In embodiments, the insulating layer may include an oxide layer and/or a nitride layer.

The insulating layer may be etched by an etch-back process to form gate spacers 13 at the sidewalls of gate 3, respectively.

Referring to FIG. 7, after gate spacers 13 are formed, a selective epitaxial growth layer SEG may be formed on a portion of semiconductor substrate SB where silicon may be exposed using an epitaxial growing process. In embodiments, since selective epitaxial growth layer SEG may be selectively formed on only the portion of semiconductor substrate SB where the silicon exists, selective epitaxial growth layer SEG may not be formed on gate spacers 13 and device isolation portions 1, but formed on photodiode PD, gates 3, and a source and a drain.

In embodiments, selective epitaxial growth layer SEG may be selectively formed on only photodiode PD, or on the source and drain disposed in both sides of gate 3. Hereinafter, the selective epitaxial growth layer formed on the source and drain may be defined as an additional selective epitaxial growth layer ASEG.

Referring to FIG. 8, after selective epitaxial growth layer SEG is formed on photodiode PD, and additional selective epitaxial growth layer ASEG may be formed on the source and drain, low concentration source 5 and low concentration drain 9 may be formed with photodiode region PDR covered with a photoresist pattern PR.

To form low concentration source 5 and low concentration drain 9, low concentration n-type impurities may be implanted at an acute angle into additional selective epitaxial growth layer ASEG of semiconductor substrate SB. As the low concentration n-type impurities may be obliquely implanted into semiconductor substrate SB, low concentration source 5 and low concentration drain 9 may not be only formed but also extend below gate spacers 13. In embodiments, since low concentration source 5 and low concentration drain 9 may be formed through additional selective epitaxial growth layer ASEG, low concentration source 5 and low concentration drain 9 may have a shallow junction characteristic.

Referring to FIG. 9, after low concentration source 5 and low concentration drain 9 may be formed, an insulating layer may be formed over a selected area, for example the entire area, of semiconductor substrate SB. In embodiments, the insulating layer may be an oxide layer and/or a nitride layer.

In embodiments, the insulating layer formed on semiconductor substrate SB may be etched using an etch-back process to form additional gate spacers 15, which may cover gate spacers 13. Additional gate spacers 15 may be formed on additional selective epitaxial growth layer ASEG.

Referring to FIG. 10, after the addition gate spacers 15 are formed, photodiode region PDR may be covered with photoresist pattern PR, high concentration n-type impurities may be implanted into driving region DR, so that a high concentration source 7 and a high concentration drain 11 may be formed in driving region DR. At this point, since high concentration source 7 and high concentration drain 11 may be formed by ion implantation through additional selective epitaxial growth layer ASEG, they may have a shallow junction characteristic.

After that, photoresist pattern PR that may have covered photodiode region PDR may be removed, so that the image sensor illustrated in FIG. 4 may be manufactured.

According to embodiments, a manufacturing process of an image sensor may be simplified and a defect caused by contamination of a photodiode of the image sensor may be prevented. Shallow junction characteristics of the source and drain of a transistor included in the image sensor may thus be realized.

It will be apparent to those skilled in the art that various modifications and variations may be made to embodiments. Thus, it is intended that embodiments cover modifications and variations thereof within the scope of the appended claims. It is also understood that when a layer is referred to as being “on” or “over” another layer or substrate, it may be directly on the other layer or substrate, or intervening layers may also be present.

What is claimed is:

1. A device, comprising:
a photodiode configured to generate charges according to light incident thereto;
a first selective epitaxial growth layer over the photodiode; and
a plurality of thin film transistors configured to output a voltage corresponding to charges output from the photodiode.

2. The device of claim 1, wherein each of the thin film transistors comprises a gate, a low concentration source and a low concentration drain provided at opposing sides of the gate, a high concentration source adjacent to the low concentration source, and a high concentration drain adjacent to the low concentration drain.

3. The device of claim 2, further comprising a second epitaxial growth layer over portions of a substrate corresponding to locations of the high concentration source and the high concentration drain.

4. The device of claim 3, further comprising first gate spacers at sides of each gate and interposed between the second selective epitaxial growth layers and each gate and between the first selective epitaxial growth layer and the gate adjacent to the first selective epitaxial growth layer.

5. The device of claim 4, further comprising second gate spacers over the first gate spacers and over at least a portion of the second selective epitaxial growth layer.

6. The device of claim 4, wherein the low concentration source and the low concentration drain overlap lower surfaces of the first gate spacers.

7. A method, comprising:
implanting ions of low concentration into a photodiode region of a semiconductor substrate to form a photodiode;
forming a gate insulating layer pattern over the semiconductor substrate in a non-photodiode region;
forming a gate electrode over the gate insulating layer pattern, the gate electrode being configured to receive charges from the photodiode; and
forming a first selective epitaxial growth layer over the photodiode.

8. The method of claim 7, further comprising forming a plurality of gate electrodes over the gate insulating layer pattern in the non-photodiode region of the semiconductor substrate.

9. The method of claim 8, further comprising:
forming first spacers at opposing sidewalls of each gate electrode;
obliquely implanting ions of low concentration into the non-photodiode region of the semiconductor substrate on opposing sides of each gate electrode to form a low concentration source and a low concentration drain extending below the first spacers; and
forming a high concentration source and a high concentration drain on sides of each gate electrode in the non-photodiode region.

10. The method of claim 9, further comprising forming a second selective epitaxial growth layer over the semiconductor substrate in the non-photodiode region after forming the first selective epitaxial growth layer, wherein the first spacers are interposed between the gate electrode and corresponding selective epitaxial growth layers.

11. The method of claim 10, further comprising forming second spacers over the first spacers and at least a portion of a surface the second selective epitaxial growth layer after the forming of the low concentration source and the low concentration drain.

12. The method of claim 8, further comprising forming the first sidewalls at sides of each gate electrode interposed between the gate electrode and second selective epitaxial growth layer, and forming second spacers over the first spacers and at least a portion of a surface the second selective epitaxial growth layer.

13. A device, comprising:
a photodiode formed in a substrate and configured to generate charges according to light incident thereto;
a first epitaxial growth layer over the photodiode;
a plurality of thin film transistors over the substrate and configured to output a voltage corresponding to charges output from the photodiode; and
a second epitaxial growth layer over selected portions of the substrate adjacent to each of the plurality of thin film transistors in a non-photodiode region of the substrate.

14. The device of claim 13, wherein each of the thin film transistors comprises a gate, a low concentration source and a low concentration drain provided at opposing sides of the gate, a high concentration source adjacent to the low concentration source, and a high concentration drain adjacent to the low concentration drain.

15. The device of claim 14, wherein the second epitaxial growth layer is over only portions of a substrate corresponding to locations of the high concentration source and the high concentration drain.

16. The device of claim 15, further comprising first gate spacers at sides of each gate and interposed between the second selective epitaxial growth layers and each gate and between the first selective epitaxial growth layer and the gate adjacent to the first selective epitaxial growth layer.

17. The device of claim 16, further comprising second gate spacers over the first gate spacers and over at least a portion of the second selective epitaxial growth layer.

18. The device of claim 17, wherein the low concentration source and the low concentration drain overlap lower surfaces of the first gate spacers.
